(19) United States
(12) Patent Application Publication
(10) Pub. No.: US 2015/0063038 A1
(43) Pub. Date: Mar. 5, 2015

(54) MEMORY CELL, MEMORY ARRAY AND OPERATION METHOD THEREOF

(71) Applicants: Chrong-Jung LIN, HSINCHU CITY (TW); Ya-Chin KING, TAIPEI CITY (TW)

(72) Inventors: Chrong-Jung LIN, HSINCHU CITY (TW); Ya-Chin KING, TAIPEI CITY (TW)

(21) Appl. No.: 14/164,242

(22) Filed: Jan. 26, 2014

(30) Foreign Application Priority Data
Aug. 29, 2013 (TW) 102131076

(51) Int. Cl. H01L 29/788; G11C 16/04

(52) U.S. Cl. CPC H01L 29/788; G11C 16/0408
USPC 365/185.29; 257/319

(57) ABSTRACT

A memory cell, a memory array and an operation method are disclosed herein. The memory cell includes a substrate with a first conductivity type, a first doped region with a second conductivity type, a second doped region with the second conductivity type, a first floating gate, a second floating gate and a word gate. The first and the second doped region are disposed in the substrate. The first floating gate is disposed on the substrate and electrically coupled to the first doped region. The second floating gate is disposed on the substrate and electrically coupled to the second doped region. The word line gate is disposed on the substrate and between the first and second doped region, wherein the word gate includes a first part extending over the first floating gate and a second part extending over the second floating gate.

### RELATED APPLICATIONS

This application claims priority to Taiwan Application Serial Number 102131076, filed Aug. 29, 2013, which is herein incorporated by reference.

### BACKGROUND

1. Field of Invention

The present invention relates to a memory cell. More particularly, the present invention relates to a memory cell having a floating gate

2. Description of Related Art

In general, a flash memory cell includes a split gate memory cell. Referring to FIG. 1A, it is a conventional side-view diagram of a split gate memory cell 100, which includes a word gate 102, a floating gate 104, a source 106 and a drain 108.

In operation, a first bias voltage (e.g., 12 Volts) is applied to the source 106, and a second bias voltage (e.g., 2.5 Volts) is applied to the drain 106, thereby generating a high electric field in horizontal in the channel. Lg, which is between the source 106 and the drain 108, to pull the electrons e⁻ in the channel Lg. The high voltage applied to the source 106 may couple to the floating gate 104, and thus generates a high electric field in vertical between the floating gate 104 and the channel Lg to pull the aforementioned electrons e− to the floating gate 104 for completing a program operation.

However, the channel Lg of the split gate memory cell 100 may be reduced by the variations of the manufacturing process, which makes the split gate memory cell 100 suffered from certain program disturbances, such as column punch through disturb, reverse tunnel disturb and row punch through disturb.

Referring to FIG. 1B, it is a split gate memory array 120 in the prior art. Taking the row punch through disturb as an example, the word lines WLm0, WLm1 are respectively electrically coupled to the word gates 102 of the aforementioned memory cells 100. In this example, when performing a program operation, a select voltage (e.g., 1.8 Volts) is applied to the word line WLm1, corresponding to the memory cell 140, the aforementioned first bias voltage (e.g., 12 Volts) is applied to the source 106 of the memory cell 140, and the aforementioned second bias voltage (e.g., 2.5 Volts) is applied to source 108 of the memory cell 140. When the length of the channel Lg is reduced by the variations of the manufacturing process, the high electric field in horizontal between the source 107 and the drain 108 may cause a drain current to generate the program disturbance. Typically, to prevent the row punch disturb, the length of the channel Lg of the split gate memory cell 100 should not be too small, which results in the increased cell size of the split gate memory cell 100.

Therefore, a heretofore unaddressed need exists in the art to address the aforementioned deficiencies and inadequacies.

### BRIEF DESCRIPTION OF THE DRAWINGS

The invention can be more fully understood by reading the following detailed description of the embodiment, with reference made to the accompanying drawings as follows:

FIG. 1A is a side view diagram of a split gate memory cell in the prior art;

FIG. 1B is a split gate memory array in the prior art;

FIG. 2A is a side view diagram of a memory cell in accordance with various embodiments of the present disclosure;

FIG. 2B is top view diagram of the split gate memory cell and the memory cell;

FIG. 3A is a side view diagram of the memory cell in accordance with another one embodiment of the present disclosure;

FIG. 3B is a side view diagram of a memory cell in accordance with yet another one embodiment of the present disclosure;

FIG. 4 is a flow chart of an operation method for a memory cell in accordance with one embodiment of the present disclosure;

FIG. 5 is a schematic diagram illustrating the relationship of the threshold voltage and the first recovery voltage of the memory cell in accordance with one embodiment of the present disclosure; and

FIG. 6 is schematic diagram of a memory array in accordance with one embodiment of the present disclosure.

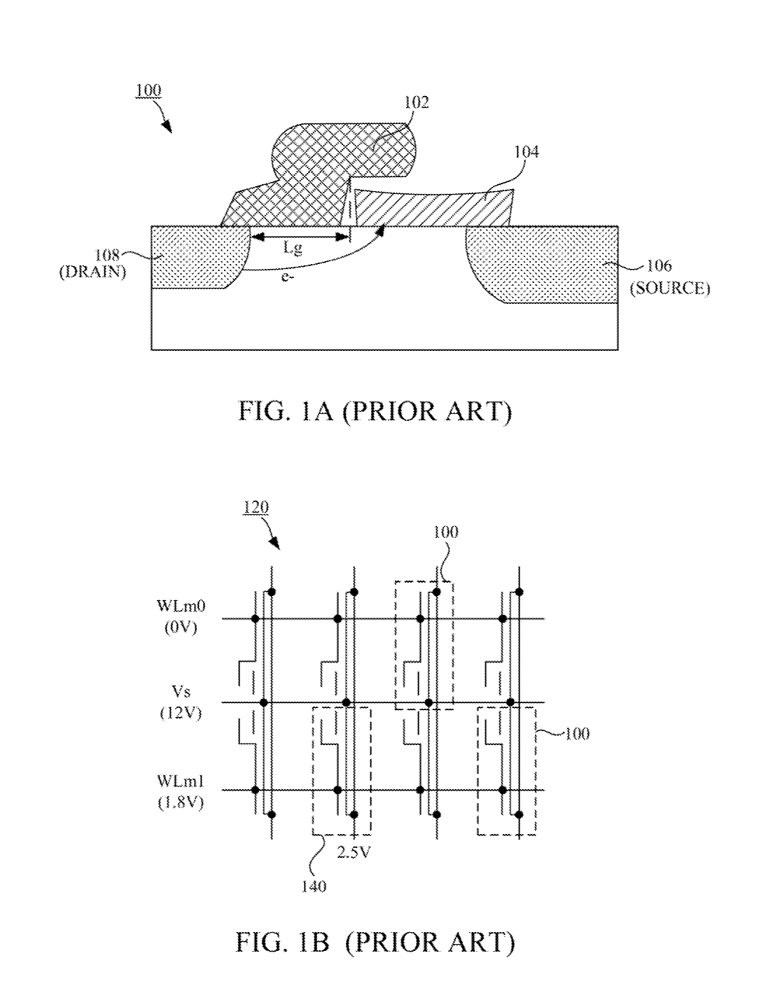

### SUMMARY

One aspect of the present disclosure is to provide a memory cell. The memory cell includes a substrate having a first conductivity type, a first doped region having a second conductivity type, a second doped region having the second conductivity type, a first floating gate, a second floating gate and a word gate. The substrate is first conductivity type, and the first doped region and the second doped region are second conductivity type. The first doped region and the second doped region are respectively disposed in the substrate. The first floating gate 240 and the second floating gate are disposed on the substrate, the first floating gate is electrically coupled to the first doped region, and the second floating gate is electrically coupled to the second doped region. The word gate is disposed on the substrate and between the first doped region and the second doped region. The word gate includes a first part extending over the first floating gate and a second part extending over the second floating gate.

Another one aspect of the present disclosure is to provide an operation method for the aforementioned memory cell. The operation method includes following steps: applying an erase voltage to the word gate and a ground voltage to the first and the second doped region to reset the memory cell; applying a select voltage to the word gate to select the memory cell; applying a write voltage to one of the first doped region and the second doped region and applying the ground voltage to another one of the first doped region and the second doped region to write data to the memory cell; and applying a read voltage to one of the first doped region and the second doped region and applying the ground voltage to another one of the first doped region and the second doped region to read the data from the memory cell.

Yet another one aspect of the present disclosure is to provide a memory array. The memory array includes word lines, pages and memory cells. Each of the pages includes a first bit line and a second bit line. The first bit line and the second bit line are disposed vertically with the word lines. Each of the memory cells includes a substrate having a first conductivity type, a first doped region having a second conductivity type, a second doped region having the second conductivity type, a first floating gate, a second floating gate and a word gate. The substrate is first conductivity type, and the first doped region and the second doped region are second conductivity type. The first doped region and the second doped region are respectively disposed in the substrate. The first floating gate 240 and the second floating gate are disposed on the substrate, the first floating gate is electrically coupled to the first doped region, and the second floating gate is electrically coupled to the second doped region. The word gate is disposed on the substrate and between the first doped region and the second doped region. The word gate includes a first part extending over the first floating gate and a second part extending over the second floating gate. The word lines, the first bit line and the second bit line are formed on the substrate.

These and other features, aspects, and advantages of the present invention will become better understood with reference to the following description and appended claims.

It is to be understood that both the foregoing general description and the following detailed description are by examples, and are intended to provide further explanation of the invention as claimed.

### DETAILED DESCRIPTION

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

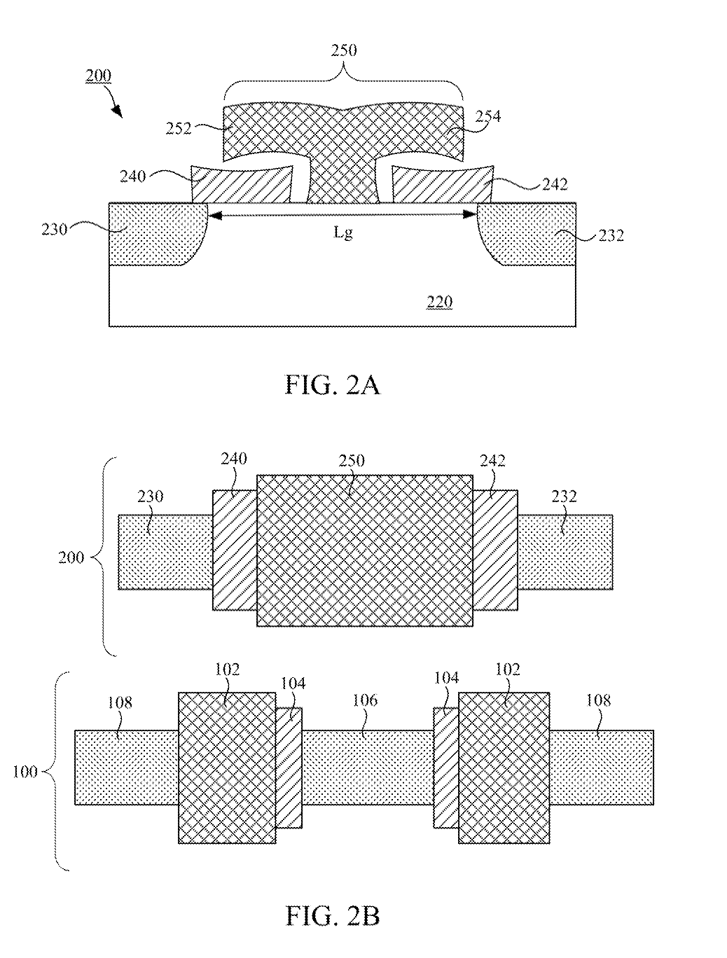

FIG. 2A is a side view diagram of a memory cell 200 in accordance with various embodiments of the present disclosure. As illustratively shown in FIG. 2, the memory cell 200 includes a substrate 220, a first doped region 230, a second doped region 232, a first floating gate 242, a second floating gate 242, and a word gate 250. The substrate 220 is first conductivity type (e.g., P type), and the first doped region 230 and the second doped region 232 are second conductivity type (e.g., N type). The first doped region 230 and the second doped region 232 are respectively disposed in the substrate 220 having the first conductivity type. The first floating gate 240 and the second floating gate 242 are disposed on the substrate 220, the first floating gate 240 is electrically coupled to the first doped region 230, and the second floating gate 242 is electrically coupled to the second doped region 232. The word gate 250 is disposed on the substrate 220 and between the first doped region 230 and the second doped region 232. The word gate 250 includes a first part 252 extending over the first floating gate 240 and a second part 254 extending over the second floating gate 240. The first floating gate 240 and the second floating gate 242 may be formed by a first poly-silicon layer, and the word gate 250 and its first part 252 and second part 254 may be formed by a second poly-silicon layer.

FIG. 2B is top view diagram of the split gate memory cell 100 and the memory cell 200. As shown in FIG. 2B, the word gate 250 of the memory cell 200 is able to control two floating gates (i.e., the first floating gate 240 and the second floating gate 242) in the same time, and thus the memory cell 200 reduces at least one source/drain region than the split gate memory cell 100 in the prior art. Therefore, the cell size of the memory cell 200 is substantially fifty to sixty percent of the cell size of the split gate cell 100. Furthermore, as shown in FIG. 2A, the channel Lg of the memory cell 200 is determined by the first floating gate 240 and the second floating gate 242. Due to the first floating gate 240 and the second floating gate 242 are the same poly-silicon layer in manufacturing process, the length of the channel Lg of the memory cell 200 is quite uniform. As a result, the affect of the program disturbance is reduced.

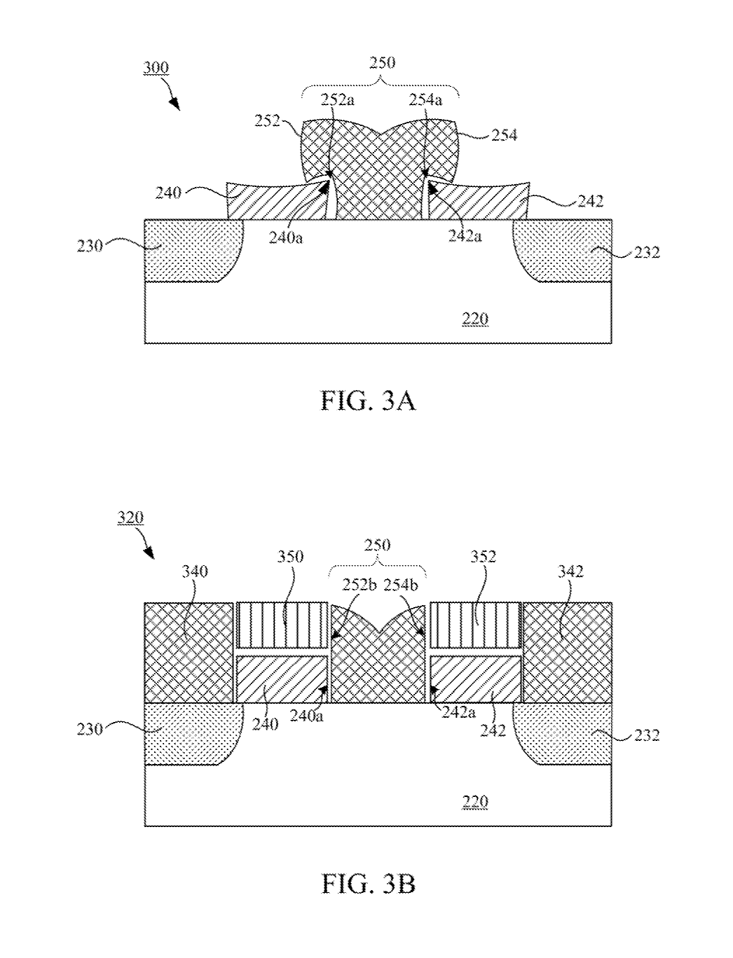

FIG. 3A is a side view diagram of the memory cell 300 in accordance with another one embodiment of the present disclosure. Compared to the aforementioned memory cell 200, the first part 252 and the word gate 250 of the memory cell 300 substantially form a first recess 252a, and the second part 254 and the word gate 250 substantially form a second recess 254a. The first floating gate 240 of the memory cell 300 includes a first tip edge 240a extending to the first recess 252a, and the second floating gate 242 includes a second tip edge 242a extending to the second recess 254a. Since the memory cell 200 erases data by pulling electrons with a high electric field, the memory cell 300 is further configured to increase the moving speed of the electrons with characteristics of tip discharging. Thus, the speed of data erasing of the memory cell 300 is improved, and an erase voltage applied to the word gate 250 is reduced (as described later).

FIG. 3B is a side-view diagram of a memory cell 320 in accordance with yet another one embodiment of the present disclosure. As shown in FIG. 3B, in the memory cell 320, a sidewall 252b of the first part 252 is substantially aligned to a sidewall 240b of the first floating gate 240, and a sidewall 254b of the second part 254 is substantially aligned to a sidewall 242b of the second floating gate 242. The memory cell 320 further includes a first erase gate 320, a second erase gate 340, a first control gate 350, and a second control gate 352. The first erase gate 340 is disposed on the first doped region 230. The second erase gate 342 is disposed on the second doped region 232. The first control gate 350 is disposed on the first floating gate 240 and between the first erase gate 340 and the sidewall 252b. The second control gate 352 is disposed on the second floating gate 242 and between the second erase gate 342 and the sidewall 254b. The first erase gate 340, the second erase gate 342 and the word gate 250 are the same poly-silicon layer, and the first control gate 350 and the second control gate 352 are third poly-silicon layer.

Compared with the memory cells 200 and 300, in this embodiment, the memory cell 320 is further configured to provide driving voltage by the extra erase gates 340, 342, and thus the erase voltage applied to the word gate 250 is reduced. Since the word gate 250 of the memory cell 320 does not need to withstand a more higher erase voltage, the thickness of the memory cell 320 is reduced. Thus, the memory cell 320 suits for an advance manufacturing process. Similarly, the control voltage applied to the word gate 250 of the memory cell 320 (as described later) during a write operation is reduced with the extra control gates 350, 352 and thus the disturbance caused during the write operation can be reduced.

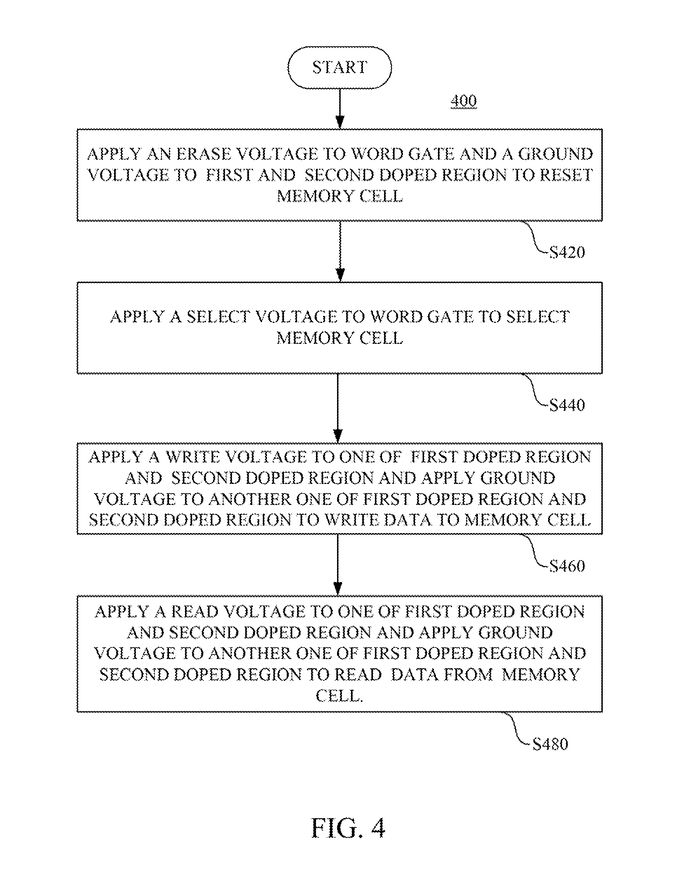

Referring to both of FIG. 4 and table 1, FIG. 4 is a flow chart of an operation method 400 for a memory cell in accordance with one embodiment of the present disclosure. Table 1 illustrates an operating configuration of the aforementioned memory cell 200.

TABLE 1

| | | | Word gate | | Doped | Doped |
|---|---|---|---|---|---|---|
| | | | 250 | | region | region |
| Operation | | | Sel. | Unsel. | 230 | 232 |
| 2-bits | Program | 1^{st} bit | 3.3 V | 0 V | 9 V | 0 V |
| | | 2^{nd} bit | | | 0 V | 9 V |
| 1-bit | Program | 0 | 3.3 V | 0 V | 9 V | 0 V |
| | | 1 | | | 0 V | 9 V |

| Self- | Floating | 1.8 V | 8 V | 0.5 V |
|---|---|---|---|---|
| recovery | gate 240 | | | |
| | Floating | | 0.5 V | 8 V |
| | gate 242 | | | |

| | | | | | |
|---|---|---|---|---|---|
| Read | Forward | 1.8 V | 0 V | 1.8 V | 0 V |
| | Reverse | 1.8 V | 0 V | 0 V | 1.8 V |

| | | |
|---|---|---|
| Erase | 11 V | 0 V |

As illustrated in table 1, the aforementioned memory cells 200, 300 and 320 can be applied to one bit operation or two bits operation. When the memory cells 200, 300 and 302 are applied to the two bits operation, the total area of the memory can be reduced. When the memory cells 200, 300 and 302 are applied to the one bit operation, the memory cells 200, 300 and 302 further include a self-recovery operation, which improves the ability of data retention of the memory cells 200, 300 and 320.

As shown in FIG. 4, the operation method 400 can be applied to the memory cells 200, 300 and 320. The following description is illustrated with the memory cell 200. The operation method 400 includes step S420, S440, S460, and S480.

At the step S420, corresponding to the erase operation listed in the table 1, an erase voltage (e.g., 11 Volts (V) illustrated in the table 1) is applied to the word gate 250 of the memory cell 200, and an operation of Folwer-Nordheim tunneling is utilized to pulled out the electrons e− of the first floating gate 240 and the second floating gate 242 with a vertical high electric field. As a result, the memory cell 200 is reset.

At the step S440, taking the two bits operation as an example, a select voltage (e.g., 3.3 Volts illustrated in the table 1) is applied to the word gate 250 of the desired memory cell 200 to select the memory cell 200.

At the step S460, taking the two bits operation as an example, a program voltage (e.g., 9 Volts illustrated in the table 1) is applied to one of the first doped region 230 and the second doped region 232 of the memory cell 200, and a ground voltage (e.g., 0 Volts illustrated in the table 1) is applied to another one of the first doped region 230 and the second doped region 232 thereby writing data to the memory cell 200. For instance, the program voltage 9 Volts is applied to the first doped region 230 of the memory cell 200, and the ground voltage 0 Volts is applied to the second doped region 232 to write data to the first bit of memory cell 200.

At the step S480, corresponding to the read operation listed in the table 1, a read voltage (e.g., 1.8 Volts illustrated in the table 1) is applied to one of the first doped region 230 and the second doped region 232 of the memory cell 200, and the ground voltage is applied to another one of the first doped region 230 and the second doped region 232. Thus, a current is accordingly generated from the channel Lg of the memory cell 200, and the data stored in the memory cell 200 are read out.

Furthermore, at the aforementioned step S460, when the memory cell 200 is applied to the one bit operation, the status of data 0 and data 1 can be further defined. The status of data 0 (i.e., the data with low logic level) is defined as the condition that the threshold voltage VTH1 of the first floating gate 240 is higher than the threshold voltage VTH2 of the second floating gate 242, which can be denoted as: logic 0=(VTH1, High, VTH2, Low). Alternatively, the status of data 1 (i.e., the data with high logic level) is defined as the condition that the threshold voltage VTH1 of the first floating gate 240 is lower than the threshold voltage VTH2 of the second floating gate 242, which can be denoted as: logic 1=(VTH1, low, VTH2, High).

Therefore, for example, the program voltage is applied to the first doped region 230 of the memory cell 200, and the ground voltage is applied to the second doped region 232, when programming data 0. Thus, the memory cell 200 utilizes the operation of source side channel hot electron injection (SSI) to inject the electron e− to the floating gate 240 from the channel Lg. At this time, the threshold voltage VTH1 is relatively higher than the threshold voltage VTH2 of the second floating gate 242, thereby writing data 0 to the memory cell 200.

Further, in the one bits operation, after programming data, one of the floating gates 240 and 242 will has a high threshold voltage. However, with long-term data storage and environmental stresses, the high threshold voltage is gradually reduced by charge loss in the floating gate. Therefore, the operation method 400 further includes an operation of self-recovery, which alternatively applies first recovery voltage (e.g., 8 Volts illustrated in the table 1) to one of the first doped region 230 and the second doped region 232 and a second recovery voltage (e.g., 0.5 Volts illustrated in the table 1) to another one of the first doped region 230 and the second doped region 232 within a predetermined time (e.g. about 100 micro-seconds), so as to self recover the data stored in the memory cell 200.

For example, it's assumed that the data 0 is already stored in the memory cell 200, which means that the electrons e− are existed in the floating gate 240. In the operation of the self-recovery, the first recovery voltage 8 Volts is applied to the first doped region 230, and the second recovery voltage 0.5 Volts is applied to the second doped region 232. Thus, a weak current is generated in the channel Lg for charging the first floating gate 240, and the second floating gate 242 is in a condition of lower threshold voltage.

Whatever data 0 or data 1 is stored in the memory cell 200, the floating gates 240 or 242, which has the higher threshold voltage, can be efficiently charged to maintain the stored data.

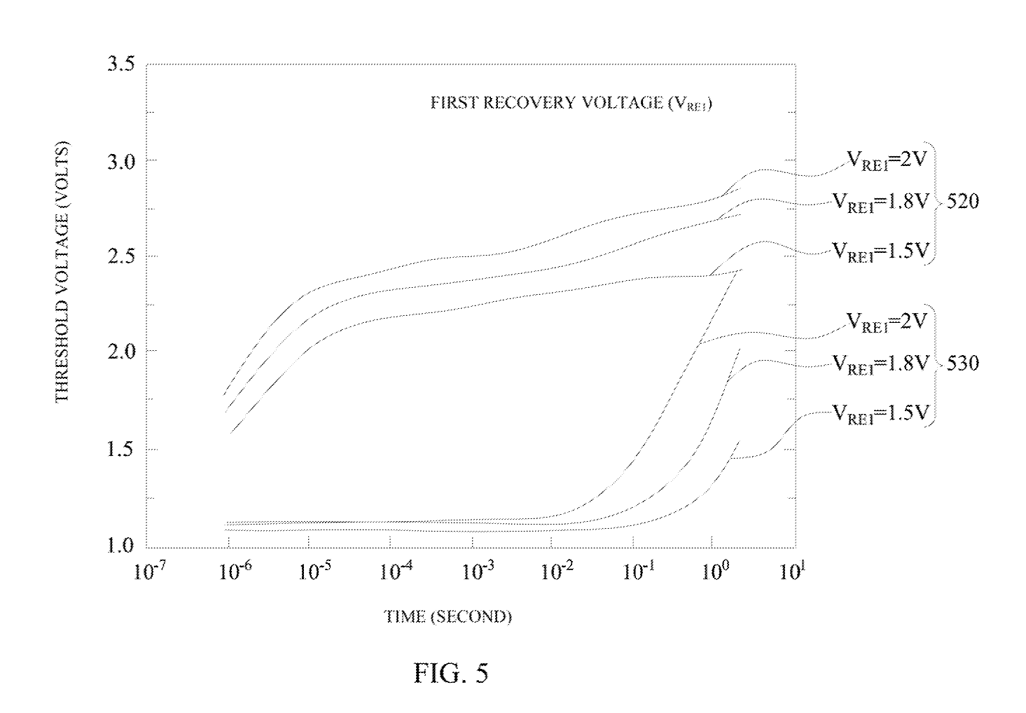

FIG. 5 is a schematic diagram illustrating the relationship of the threshold voltage and the first recovery voltage of the memory cell 200, in accordance with one embodiment of the present disclosure.

As shown in FIG. 5, vertical axis represents one of the threshold voltage VTH1 of the first floating gate 240 and the threshold voltage VTH2 of the second floating gate 242. FIG. 5 includes a group of curves 520 and a group of curves 530, the group of curves 520 corresponds to the floating gate with a higher threshold voltage, and the group of curves 530 corresponds to the floating gate with a lower threshold voltage. As shown in FIG. 5, in the operation of the self-recovery, the floating gate with the higher threshold voltage in the memory cell 200 can be charged completely in about 20 microseconds, and the floating gate with the lower threshold voltage is not disturbed by the program disturbances within about 200 milliseconds.

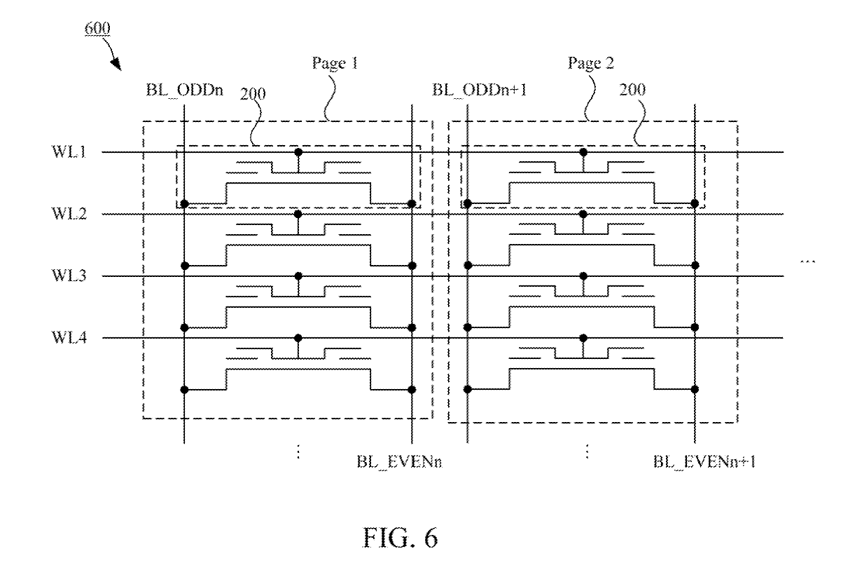

FIG. 6 is schematic diagram of a memory array 600 in accordance with one embodiment of the present disclosure. As shown in FIG. 6, the memory array 600 includes a plurality of word lines WL1˜WLm and a plurality of pages Page1˜Pagen. For illustration, FIG. 6 only shows the word lines WL1˜WL4 and pages page1˜page2.

Taking the page1 as an example, each pages includes a first bit line BL_ODDn and a second bit line BL_Evenn and the aforementioned memory cells 200 (or the memory cell 300). The first bit line BL_ODDn and the second bit line BL_Evenn are disposed vertically with the word lines WL1˜WL4. The word gates 250 of the memory cell 200 are electrically coupled to the corresponding word line respectively. For instance, the word gate of the memory cells 200 in the first row of the page1 and page2 are electrically coupled to the word line WL1. The first doped region 230 of the memory cells 200 are electrically coupled to the first bit line BL_ODDn, and the second doped region 232 are electrically coupled to the second bit line BL_EVENn. The aforementioned word lines WL1˜WLm, first bit lines BL_ODDn and the second bit lines BL_EVENn are formed on the substrate 200.

In some embodiments, the memory array 600 performs the operations of program, read, erase or the self-recovery by applying corresponding voltages to the word line and the bit line with reference to the table 1. The same operations are not described here.

Moreover, the aforementioned memory array 600 can further directly connect the second bit line BL_EVENn of the page1 of current stage to the first bit line BL_ODDn+1 of the page2 of next stage. As a result, by sharing one bit line, the area of the memory array 600 can be reduced.

However, when sharing the same bit line (i.e., BL_EVENn and BL_ODDn+1), the operations of the memory array 600 are a little bit different to the operations illustrated above in the table 1. For example, when programming data 0 to the memory cells 200 of the page page1, the program voltage is applied to the first bit line BL_ODDn and the ground voltage is applied to the second bit line BL_EVENn (i.e., BL_ODDn+1). In the same time, the ground voltage is required to apply to the second bit line BL_EVENn+1 of the page page2 to prevent from incorrectly programming data to the memory cells of the page page2. Similarly, there is an analogous operation on the page page2, when programming data 1 to the memory cells 200 of the page page2, which will not be described here.

The aforementioned memory array 600 can be adapted to the memory cell 200 or the memory cell 300. Any one who has ordinary skill in the art can choose one of the memory cells 200 and 300 in accordance with the practical applications.

In summary, the memory cells, the memory array and the operation method described in the present disclosure can achieve a smaller cell size, and low program disturbances and self-recovery operation for data.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

1. A memory cell, comprising:
a substrate having a first conductivity type;
a first doped region having a second conductivity type disposed in the substrate;
a second doped region having the second conductivity type disposed in the substrate;
a first floating gate disposed on the substrate and electrically coupled to the first doped region;
a second floating gate disposed on the substrate and electrically coupled to the second doped region; and
a word gate disposed on the substrate and between the first doped region and the second doped region, the word gate comprising a first part extending over the first floating gate and a second part extending over the second floating gate.

2. The memory cell of claim 1, wherein the first part and the word gate substantially form a first recess, and the second part and the word gate substantially form a second recess, wherein the first floating gate comprises a first tip edge extending to the first recess, and the second floating gate comprises a second tip edge extending to the second recess.

3. The memory cell of claim 1, wherein a sidewall of the first part is substantially aligned to a sidewall of the first floating gate, a sidewall of the second part is substantially aligned to the a sidewall of the second floating gate, wherein the memory cell further comprising:
a first erase gate disposed on the first doped region;
a second erase gate disposed on the second doped region;
a first control gate disposed on the first floating gate, and between the first erase gate and the sidewall of the first part; and
a second control gate disposed on the second floating gate and between the second erase gate and the sidewall of the second part.

4. An operation method for a memory cell, the memory cell comprising a substrate having a first conductivity type, a first doped region and a second doped region having a second conductivity type, a first floating gate a second floating gate and a word gate, the first and the second doped region being disposed in the substrate, the first and the second floating gate being disposed on the substrate, the first floating gate being electrically coupled to the first doped region, the second floating gate being electrically coupled to the second doped region, the word gate being disposed on the substrate and between the first and the second doped region, the word gate comprising a first part extending over the first floating gate and a second part extending over the second floating gate, the operation method comprising:
applying an erase voltage to the word gate and a ground voltage to the first and the second doped region to reset the memory cell;
applying a select voltage to the word gate to select the memory cell;
applying a write voltage to one of the first doped region and the second doped region and applying the ground voltage to another one of the first doped region and the second doped region to write data to the memory cell; and
applying a read voltage to one of the first doped region and the second doped region and applying the ground voltage to another one of the first doped region and the second doped region to read the data from the memory cell.

5. The operation method of claim 4, wherein the first part and the word gate substantially form a first recess, and the second part and the word gate substantially form a second recess, wherein the first floating gate has a first tip edge, and the second floating gate has a second tip edge extending to the first recess.

6. The operation method of claim 4, wherein a sidewall of the first part is substantially aligned to a sidewall of the first floating gate, a sidewall of the second part is substantially aligned to the a sidewall of the second floating gate, wherein the memory cell further comprises:
a first erase gate disposed on the first doped region;
a second erase gate disposed on the second doped region;
a first control gate disposed on the first floating gate, and between the first erase gate and the sidewall of the first part; and
a second control gate disposed on the second floating gate, and between the second erase gate and the sidewall of the second part.

7. The operation method of claim 4, further comprising:
alternatively applying a first recovery voltage to one of the first doped region and the second doped region and a second recovery voltage to another one of the first doped region and the second doped region, so as to self recover the data stored in the memory cell.

8. The operation method of claim 5, further comprising:
alternatively applying a first recovery voltage to one of the first doped region and the second doped region and a second recovery voltage to another one of the first doped region and the second doped region, so as to self recover the data stored in the memory cell.

9. The operation method of claim 6, further comprising:
alternatively applying a first recovery voltage to one of the first doped region and the second doped region and a second recovery voltage to another one of the first doped region and the second doped region, so as to self recover the data stored in the memory cell.

10. A memory array, comprising:
a plurality of word lines;
a plurality of pages, wherein each of the pages comprising:
a first bit line; and
a second bit line, wherein the first bit line and the second bit line are disposed vertically with the word lines; and
a plurality of memory cells, each of the memory cells comprising:
a substrate having a first conductivity;
a first doped region having a second conductivity disposed in the substrate, wherein the first doped region is electrically coupled to the first bit line;
a second doped region having the second conductivity disposed in the substrate, wherein the first doped region is electrically coupled to the second bit line;
a first floating gate disposed on the substrate, wherein the first floating gate is electrically coupled to the first doped region;
a second floating gate disposed on the substrate, wherein the second floating gate is electrically coupled to the second doped region; and
a word gate disposed on the substrate and between the first and the second doped region, and electrically coupled to a corresponding one of the word lines, the word gate comprising a first part extending over the first floating gate and a second part extending over the second floating gate;
wherein the word lines, the first bit line and the second bit line are formed on the substrate.

11. The memory array of the claim 10, wherein the first part and the word gate substantially form a first recess, the second part and the word gate substantially form a second recess, wherein the first floating gate has a first tip edge, and the second floating gate has a second tip edge extending to the first recess.

12. The memory array of the claim 10, wherein the second bit line of the page of current stage is directly connected to the first bit line of the page of next stage.

13. The memory array of the claim 11, wherein the second bit line of the page of current stage is directly connected to the first bit line of the page of next stage.
